(19) United States
(12) Patent Application Publication
(10) Pub. No.: US 2012/0018197 A1
(43) Pub. Date: Jan. 26, 2012

(54) NOVEL DUCTILE METAL FOIL LAMINATE AND METHOD FOR PRODUCING THE SAME

(75) Inventors: Young Seok Park, Suwon-si (KR); Eun Song Baik, Asan-si (KR); Yang Seob Kim, Seoul (KR); Dong Bo Yang, Yongin-si (KR)

(73) Assignee: DOOSAN CORPORATION, Seoul (KR)

(21) Appl. No.: 13/145,959

(22) PCT Filed: Jan. 22, 2010
(86) PCT No.: PCT/KR10/00422

§ 371 Date: Sep. 30, 2011

(30) Foreign Application Priority Data
Jan. 23, 2009 (KR) 10-2009-0006195

(51) Int. Cl. H05K 1/00; B32B 7/02; B32B 37/12; B32B 27/08

(52) U.S. Cl. 174/254; 428/414; 428/216; 156/182

(57) ABSTRACT

Provided are a flexible metal clad laminate including: (a) a first conductive metal foil in which a first polyimide layer is formed on a surface thereof; and (b) a second conductive metal foil in which a second polyimide layer is formed on a surface thereof, wherein the first polyimide layer and the second polyimide layer are joined together by an epoxy adhesive, and a method of manufacturing the same. The inventive flexible metal clad laminate can maintain the intrinsic properties of polyimide, and thus, can exhibit good heat resistance and flexibility to comparable with a conventional two-layer, double-sided flexible copper clad laminate, and a manufacturing process thereof is simple and easy, thus ensuring enhanced productivity and economical effectiveness.

### TECHNICAL FIELD

The present invention relates to a novel double-sided flexible metal clad laminate capable of satisfying with the requirements for flexible copper clad laminates, i.e., flexibility, heat and chemical resistance, flame retardance, and electrical properties, and a method of manufacturing the same in a simple and economical manner.

### BACKGROUND ART

Flexible copper clad laminates (FCCLs), also called ductile copper foil laminates, are used mainly as substrates of flexible printed circuit boards. In addition, FCCLs are used in sheet-type heaters, electromagnetic wave shielding materials, flat cables, packaging materials, etc. As a recent trend in electronic machines employing printed circuit boards is toward miniaturization, high density and high efficiency, there is an increasing use of double-sided FCCLs.

FCCLs are largely divided into two-layer (copper-polyimide) FCCLs and three-layer (copper-epoxy-polyimide) FCCLs. With respect to conventional three-layer, double-sided FCCLs, as shown in FIG. 1, an epoxy resin is coated on both surfaces of a polyimide film, and a copper foil is joined to each of the epoxy resin layers, thus enabling a relatively simplified manufacturing process. However, since such FCCLs are structured such that a copper foil is directly contacted to an epoxy resin layer, all physical properties (e.g., heat and chemical resistance, flame retardance, electrical properties) of finally produced laminates are affected by the epoxy resin used, and thus, it is difficult to sufficiently exhibit intrinsic good properties (in particular, flexibility, heat resistance, insulation withstand capability) of polyimide.

In view of these problems, two-layer, double-sided FCCLs employing only polyimide as an adhesive, without using an epoxy adhesive, have been used. Such FCCLs exhibit good heat resistance and excellent flexibility due to the use of only polyimide as an adhesive, and thus, have been used in many fields requiring flexibility. For example, two-layer FCCLs have been widely used in electronic products such as laptop computers, mobile phones, PDAs, digital cameras, etc. Among two-layer FCCLs, there is an increasing use of two-layer, double-sided FCCLs in which a copper foil is formed on both surfaces of a polyimide layer, with a recent trend toward thinner and more integrated circuits. However, these two-layer, double-sided FCCLs are process-ineffective due to complicated and prolonged manufacturing process.

Therefore, the development of new FCCLs capable of exhibiting performance comparable with two-layer, double-sided FCCLs and being manufactured in a relatively simple process is needed.

### DETAILED DESCRIPTION OF THE INVENTION

### Technical Goal of the Invention

Conventional flexible copper clad laminates employing an epoxy adhesive layer have been increasingly used due to a simple fabrication process and good adhesion property. However, an epoxy adhesive layer exhibits lower flexibility and heat resistance relative to a polyimide layer, and thus, there is a limitation to the use of an epoxy adhesive layer in the fields requiring good flexibility and heat resistance. In this respect, needs for improving the flexibility and heat resistance of flexible copper clad laminates employing an epoxy adhesive layer have been continuously addressed.

While searching for a solution to the above-described problems, the present inventors developed a new flexible metal clad laminate capable of exhibiting the intrinsic good properties of polyimide, i.e., good flexibility, heat and chemical resistance, flame retardance and electrical properties, and a method of simply manufacturing the same.

Therefore, the present invention provides a new double-sided flexible metal clad laminate capable of exhibiting good physical properties and a method of manufacturing the same in a simple and economical manner.

The present invention is not limited to the above-described objects, and other objects of the present invention would be fully conceived by one of ordinary skill in the art from the following description.

### Structure and Operation of the Invention

According to an aspect of the present invention, there is provided a flexible metal clad laminate including: (a) a first conductive metal foil in which a first polyimide layer is formed on a surface thereof; and (b) a second conductive metal foil in which a second polyimide layer is formed on a surface thereof, wherein the first polyimide layer and the second polyimide layer are joined together by an epoxy adhesive.

The flexible metal clad laminate may include a sequentially stacked array of (a) the first conductive metal foil, (b) the first polyimide layer, (c) an epoxy adhesive layer, (d) the second polyimide layer, and (e) the second conductive metal foil.

Each of the first and second conductive metal foils may have a thickness ranging from 5 to 40 μm, each of the first and second polyimide layers may have a thickness ranging from 2 to 60 μm, and the epoxy adhesive may be formed to a thickness ranging from 2 to 60 μm.

Each of the first and second conductive metal foils may be made of copper, tin, gold, silver or a combination thereof.

An inorganic filler reducing coefficient of thermal expansion (CTE) of the first and second polyimide layers may be uniformly distributed or localized in each of the first and second polyimide layers.

According to another aspect of the present invention, there is provided a method of manufacturing the above-described flexible metal clad laminate, the method including: (a) forming a first polyimide layer on a first conductive metal foil, followed by curing; (b) forming a second polyimide layer on a second conductive metal foil, followed by curing; and (c) coating an epoxy adhesive on at least one of the first polyimide layer and the second polyimide layer, followed by drying so that the epoxy adhesive is in a semi-cured state, and joining the first polyimide layer and the second polyimide layer.

### Effect of the Invention

The inventive flexible metal clad laminate can maintain the intrinsic properties of polyimide, and thus, can exhibit good heat resistance and flexibility comparable with a conventional two-layer, double-sided flexible copper clad laminate, and a manufacturing process thereof is simple and easy, thus ensuring enhanced productivity and economical effectiveness.

### BRIEF DESCRIPTION OF THE DRAWINGS

FIG. 1 is a sectional view illustrating a conventional flexible copper clad laminate (Comparative Example 1).

FIG. 2 is a sectional view illustrating a flexible metal clad laminate according to an embodiment of the present invention.

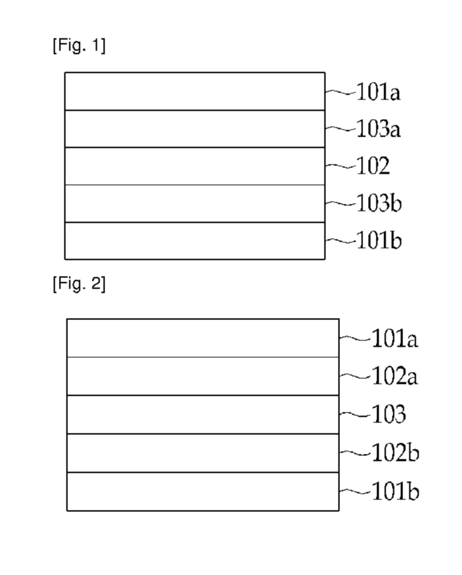

### EXPLANATION OF REFERENCE NUMERALS DESIGNATING THE MAJOR ELEMENTS OF THE DRAWINGS

101a, 101b: metal foil
102, 102a, 102b: polyimide
103, 103a, 103b: epoxy adhesive

### BEST MODE FOR CARRYING OUT THE INVENTION

Hereinafter, the present invention will be described in more detail.

The present invention provides a flexible metal clad laminate capable of exhibiting the intrinsic properties of polyimide, i.e., good flexibility, heat and chemical resistance, flame retardance and electrical properties, and a method of simply manufacturing the same.

For this, the inventive flexible metal clad laminate is structured such that a first polyimide layer is formed on a surface (e.g., a first surface) of a first conductive metal foil, a second polyimide layer is formed on a surface (e.g., a first surface) of a second conductive metal foil, and the first and second polyimide layers are joined together by an epoxy adhesive.

The first and second conductive metal foils are respectively contacted to the first and second polyimide layers, instead of the epoxy adhesive layer, and the first and second polyimide layers completely surround the epoxy adhesive layer centered in the flexible metal clad laminate. Therefore, the inventive flexible metal clad laminate can sufficiently exhibit intrinsic good properties of polyimide while maintaining effects due to the use of the epoxy adhesive (see Table 3).

Conventional flexible metal clad laminates employing polyimide as an adhesive are process-ineffective due to the use of expensive to polyimide and severe adhesion conditions (e.g., high temperature, high pressure). On the contrary, the inventive flexible metal clad laminate employs an epoxy adhesive, and thus, can solve the above-described problems, thereby ensuring enhanced productivity and economical effectiveness.

Hereinafter, the inventive flexible metal clad laminate will be described in detail with reference to the accompanying drawings.

FIG. 2 is a sectional view illustrating a flexible metal clad laminate according to an embodiment of the present invention.

Referring to FIG. 2, the inventive flexible metal clad laminate is structured such that a first polyimide layer 102a is formed on a surface of a first conductive metal foil 101a, a second polyimide layer 102b is formed on a surface of a second conductive metal foil 101b, and an epoxy adhesive layer 103 is formed between the first polyimide layer 102a and the second polyimide layer 102b so that the first and second polyimide layers 102a and 102b are joined together.

According to a preferred embodiment of the present invention, the inventive flexible metal clad laminate may include a sequentially stacked array of the first conductive metal foil 101a, the first polyimide layer 102a, the epoxy adhesive layer 103, the second polyimide layer 102b, and the second conductive metal foil 101b.

The materials of the first and second conductive metal foils 101a and 101b are not particularly limited provided that they are metals exhibiting conductivity and ductility. For example, the first and second conductive metal foils 101a and 101b may be made of copper (Cu), tin, gold, silver or a combination thereof, preferably copper. As for a copper foil, a rolled copper foil or an electrolytic copper foil may be used.

The first conductive metal foil may be made of a material different from that of the second conductive metal foil. Preferably, however, the first and second conductive metal foils may be made of the same material. The thicknesses of the first and second conductive metal foils are not particularly limited, but may range from 5 to 40 μm, more preferably from 9 to 35 μm.

The first and second polyimide layers formed on the first and second conductive metal foils may be made of a polyimide (Pp-based resin commonly known in the art.

Polyimide (PI), which is a polymer material having an imide ring, exhibits good heat, chemical and abrasion resistance, weatherability, etc. due to the chemically stable imide ring. In addition, polyimide can exhibit low thermal expansion, low air permeability, good electrical properties, etc. Polyimide is generally synthesized by condensation polymerization of aromatic dianhydride and aromatic diamine (or aromatic diisocyanate), and can be divided into \textcircled{1} straight-chain, thermoplastic polyimide, \textcircled{2} straight-chain, non-thermoplastic polyimide, and \textcircled{3} thermosetting polyimide according to the molecular structure and processibility of a finally produced polymer solid. Thermosetting polyimide is preferred. A material of the first polyimide layer may be the same as or different from that of the second polyimide layer.

The thicknesses of the first and second polyimide layers are not particularly limited, but may range from 2 to 60 μm, more preferably from 3 to 30 μm. The thickness of the first polyimide layer may be the same as or different from that of the second polyimide layer.

In order to reduce the difference of coefficient of thermal expansion (CTE) between a polyimide layer and a metal foil, an inorganic filler capable of reducing the CTE of polyimide may be uniformly distributed or localized in each of the first and second polyimide layers.

An adhesive material for joining the first and second polyimide layers is an epoxy-based resin commonly known in the art, i.e., an epoxy adhesive containing at least one epoxy group at a molecule thereof.

The thickness of the epoxy adhesive layer is not particularly limited, but may range from 2 to 60 μm, more preferably from 4 to 30 μm. Preferably, the total thickness of an insulating film including the first and second polyimide layers and the epoxy adhesive layer may range from 10 to 50 μm.

According to the present invention, there is no need to repeatedly perform a coating process and a stacking process, unlike a conventional polyimide-copper clad laminate. That is, the inventive flexible metal clad laminate can be manufactured by a method including preparing polyimide-metal clad laminates (e.g., each laminate is structured such that a thermosetting polyimide layer is formed on a metal foil) and joining two of the polyimide-metal clad laminates by an epoxy adhesive.

In the present invention, the epoxy adhesive layer is mono-layered, thus enabling a simple manufacturing process and good heat resistance, flexibility, etc. comparable with a conventional two-layer copper clad laminate.

The inventive flexible metal clad laminate may be manufactured by a method including the following steps: (a) forming a first polyimide layer on a surface of a first conductive metal foil, followed by curing; (b) forming a second polyimide layer on a second conductive metal foil, followed by curing; and (c) coating an epoxy adhesive on at least one of the first and second polyimide layers, followed by drying so that the epoxy adhesive is in a semi-cured state, and joining the first polyimide layer and the second polyimide layer.

First, the first and second polyimide layers are respectively formed on the first and second conductive metal foils (steps (a) and (b)).

The first and second polyimide layers may each be formed by a casting method including: coating on a copper foil a polyamic acid varnish obtained by the reaction of dianhydride and diamine, followed by drying and imidization.

In more detail, for example, a structure of a thermosetting polyimide layer on a copper foil may be formed by a method including: dissolving aromatic tetracarboxylic dianhydride and aromatic diamine in a polar solvent to prepare a polyamic acid solution and coating the polyamic acid solution on a copper foil, followed by thermal treatment.

Examples of dianhydride used in the preparation of the polyamic acid include, but are not limited to, pyromellitic dianhydride (PMDA:), 3,3′,4,4′-biphenyltetracarboxylic dianhydride (BPDA:), 3,3′,4,4′-benzophenonetetracarboxylic dianhydride (BTDA:), to 4,4′-oxydiphthalic anhydride (ODPA), 4,4′-isopropylidenediphenoxy-bis(phthalic anhydride) (BPADA), 2,2′-bis-(3,4-dicarboxyphenyl)hexafluoropropane dianhydride (6FDA), ethylene glycol bis(anhydro-trimellitate) (TMEG), hydroquinone diphthalic anhydride (HQDEA), 3,4,3′,4′-diphenylsulfonetetracarboxylic dianhydride (DSDA) and combinations thereof. A combination of two or more of the above-described dianhydrides is preferred.

Examples of the diamine include, but are not limited to, p-phenylene diamine (p-PDA), m-phenylene diamine (m-PDA), 4,4′-oxydianiline (4,4′-ODA), 2,2-bis(4-[4-aminophenoxy]phenyl)propane (BAPP), 2,2′-dimethyl-4,4′-diaminobiphenyl (m-TB-HG), 1,3-bis(4-aminophenoxy) benzene (TPER), 2,2-bis(4-[3-aminophenoxy]phenyl) sulfone (m-BAPS), 4,4′-diamino benzanilide (DABA), 4,4′-bis(4-aminophenoxy)biphenyl, and combinations thereof. A combination of two or more of the above-described diamines is preferred.

An appropriate amount of an inorganic filler may be used in the preparation of the polyamic acid solution.

The CTE of a general polyimide resin is 20-50 ppm, whereas that of a copper foil is 18 ppm. Due to such CTE difference of these two materials, a finally produced flexible metal clad laminate may undergo unwanted bending. An inorganic filler serves to reduce a CTE difference between a polyimide resin and a copper foil, thereby ensuring improved bending characteristic, low expansion, and furthermore, enhanced mechanical properties and low stress of finally produced metal clad laminates.

Examples of the inorganic filler as used herein include, but are not limited to, talc, mica, silica, calcium carbonate, magnesium carbonate, clay, calcium silicate, titanium oxide, antimony oxide, glass fiber and combinations thereof. The inorganic filler may be used in an amount of 10 wt % or more and less than 30 wt %, based on the total weight (100 wt %) of all the reactants for the preparation of the polyamic acid, but the present invention is not limited thereto.

Examples of the solvent used in the preparation of the polyamic acid varnish include, but are not limited to, N-methylpyrrolidinone (NMP), N,N-dimethylacetamide (DMAc), tetrahydrofuran (THF), N,N-dimethylformamide (DMF), dimethylsulfoxide (DMSO), cyclohexane, acetonitrile, alone or in combination of two or more thereof.

If necessary, dianhydrides or diamines other than the above-exemplified compounds, or other additive(s) may be used in small amounts, which is also within the scope of the present invention.

The polyamic acid varnish may have a viscosity of 3,000 to 50,000 cps, but the present invention is not limited thereto. In the coating of the polyamic acid varnish on a metal foil, a coating thickness may be changed according to the concentration of polyamic acid, but may be adjusted so that a polyimide layer obtained after imidization has a thickness ranging from 2 to 60 μm, preferably from 3 to 30 μm.

Next, in order to join the first and second polyimide layers, an epoxy adhesive is coated on at least one of the first polyimide layer and the second polyimide layer, followed by drying so that the epoxy adhesive is in a semi-cured state, and the epoxy adhesive is then cured so that the first and second polyimide layers are joined together (step (c)).

The epoxy adhesive used to join the first and second polyimide layers should satisfy with good heat resistance, flame retardance, flexibility, etc. For this, a halogen-free epoxy resin commonly known in the art, preferably an eco-friendly halogen-free epoxy resin, may be used. In order to satisfy with good heat resistance, flame retardance, flexibility, etc., various materials, including the following non-limiting examples, i.e., a carboxyl group-containing acryl resin, a carboxyl group-containing acrylonitrile-butadiene rubber, (meth)acrylic ester, (meth)acrylonitrile, unsaturated carboxylic acid, and other components commonly known in the art may be used in combination with the epoxy adhesive.

Halogen-Free Epoxy Resin

A halogen-free epoxy resin is an epoxy resin that contains no halogen atoms (e.g., bromine) at its molecule. Such an epoxy resin is not particularly limited, and may include silicone, urethane, polyimide, polyamide, etc. A halogen-free epoxy resin may also include a phosphorous atom, a sulfur atom, a nitrogen atom, etc. at its skeleton.

Examples of a halogen-free epoxy resin include, but are not limited to, bisphenol A epoxy resins, bisphenol F epoxy resins, and hydrogenated products thereof; glycidyl ether-based epoxy resins such as phenol novolac epoxy resins and cresol novolac epoxy resins; glycidyl ester-based epoxy resins such as glycidyl hexahydrophthalate and dimer acid glycidyl ester; glycidyl amine-based epoxy resins such as triglycidyl isocyanurate and tetraglycidyldiaminodiphenylmethane; linear aliphatic epoxy resins such as epoxidated polybutadiene and epoxidated soybean oil.

In addition, various phosphorus-containing epoxy resins produced by binding phosphorus atoms to an epoxy resin using a reactive phosphorus compound may also be effectively used in the preparation of a halogen-free flame retardant adhesive composition.

Carboxyl Group-Containing Acryl Resin and/or Carboxyl Group-Containing Acrylonitrile-Butadiene Rubber

A carboxyl group-containing acryl resin and/or a carboxyl group-containing acrylonitrile-butadiene rubber (hereinafter, “acrylonitrile-butadiene rubber” is referred to as “NBR”) may be used.

A carboxyl group-containing acryl resin may be a resin imparting an appropriate tackiness, having a glass transition temperature (T_{g}) of −40˜30° C. for good handling property, and including acrylic ester as a main component and a small amount of a carboxyl group-containing monomer. Preferably, a carboxyl group-containing acryl resin may have a glass transition temperature (T_{g}) ranging from −10 to 25° C.

The weight average molecular weight of a carboxyl group-containing acryl resin may range from 100,000 to 1000,000, preferably from 300,000 to 850,000, as measured by gel permeation chromatography (GPC, based on polystyrene calibration standards). For example, such a carboxyl group-containing acryl resin may be an acryl-based polymer obtained by copolymerization of (a) acrylic ester and/or methacrylic ester, (b) acrylonitrile and/or methacrylonitrile, and (c) unsaturated carboxylic acid. The acryl-based polymer may be a copolymer consisting of the components (a) to (c), or alternatively a copolymer including commonly available monomer(s) or oligomer(s), in addition to the components (a) to (c).

(a) (Meth)acrylic ester

Acrylic ester and/or methacrylic ester can impart flexibility to an acryl-based adhesive composition.

Examples of acrylic ester as used herein include, but are not limited to, methyl(meth)acrylate, ethyl(meth)acrylate, n-butyl(meth)acrylate, isobutyl(meth)acrylate, isopentyl(meth)acrylate, n-hexyl(meth)acrylate, isooctyl(meth)acrylate, 2-ethylhexyl(meth)acrylate, n-octyl(meth)acrylate, isononyl(meth)acrylate, n-decyl(meth)acrylate, isodecyl(meth)acrylate, etc. Among them, it is preferable to use alkyl(meth)acrylic ester having an alkyl group of 1 to 12, in particular 1 to 4 carbon atoms. These (meth)acrylic esters may be used alone or in combination of two or more.

The content of the (meth)acrylic ester may range from 50 to 80 wt %, preferably from 55 to 75 wt %, based on the total weight (100 wt %) of an epoxy adhesive composition.

(b) (Meth)acrylonitrile

Acrylonitrile and/or methacrylonitrile can impart heat resistance, adhesion property and chemical resistance to an adhesive sheet. The content of (meth)acrylonitrile may range from 15 to 45 wt %, more preferably from 20 to 40 wt %, based on the total weight (100 wt %) of an epoxy adhesive composition.

(c) Unsaturated Carboxylic Acid

An unsaturated carboxylic acid imparts adhesiveness, and also functions as a cross-linking point during heating. A copolymerizable vinyl monomer having a carboxyl group may be used. Examples of the unsaturated carboxylic acid as used herein include, but are not limited to, acrylic acid, methacrylic acid, crotonic acid, maleic acid, fumaric acid, itaconic acid, etc.

The content of the unsaturated carboxylic acid may range from 2 to 10 wt %, more preferably from 2 to 8 wt %, based on the total weight (100 wt %) of an epoxy adhesive composition.

Examples of the carboxyl group-containing acryl resin include commercially available Paracron ME-3500-DR (Negami Chemical Industrial Co., Ltd., glass transition temperature: −35° C., weight average molecular weight: 600,000, COON group-containing), Teisan Resin WS023DR (Nagase ChemteX Corp., glass transition temperature: −5° C., weight average molecular weight: 450,000, OH/COOH group-containing), Teisan Resin SG-280DR (Nagase ChemteX Corp., glass transition temperature: −30° C., weight average molecular weight: 900,000, COON group-containing), Teisan Resin SG-708-6DR (Nagase ChemteX Corp., glass transition temperature: 5° C., weight average molecular weight: 800,000, OH/COOH group-containing), etc. These carboxyl group-containing acryl resins may be used alone or in combination of two or more.

Examples of the carboxyl group-containing NBR as used herein include rubbers produced by carboxylating the molecular chain terminals of a copolymer rubber prepared by copolymerization of acrylonitrile and butadiene so that the content of acrylonitrile ranges from 5 to 70 wt %, particularly preferably from 10 to 50 wt %, based on the total weight (100 wt %) of acrylonitrile and butadiene; and copolymer rubbers produced by copolymerization of acrylonitrile, butadiene and a carboxyl group-containing monomer such as acrylic acid or maleic acid. The above carboxylation may be conducted using a carboxyl group-containing monomer such as methacrylic acid. The proportion of carboxyl groups in the carboxyl group-containing NBR (i.e., the ratio of carboxyl group-containing monomers relative to all the monomers constituting the carboxyl group-containing NBR) is not particularly limited, but may range from 1 to 10 mol %, particularly preferably from 2 to 6 mol %. If the proportion of carboxyl groups in the carboxyl group-containing NBR satisfies with the above range, it is possible to control the fluidity of an adhesive composition, thereby ensuring good curability.

Specific examples of such a carboxyl group-containing NBR include commercially available Nipol 1072 (Zeon Corp.) and high purity, low ionic impurity product PNR-1H (JSR Corp.). High-purity carboxyl group-containing acrylonitrile-butadiene rubbers are very expensive and thus cannot be used in large amounts, but are effective in simultaneously enhancing adhesion and anti-migration properties. The content of the carboxyl group-containing NBR is not particularly limited, but may range from 10 to 200 parts by weight, preferably from 20 to 150 parts by weight, based on 100 parts by weight of the halogen-free epoxy resin. If the content of the carboxyl group-containing NBR satisfies with the above range, a finally produced flexible metal clad laminate can exhibit excellent flame retardance and peel strength of a copper foil. The carboxyl group-containing acryl resin and the carboxyl group-containing NBR may each be used alone or in combination of two or more.

Curing Agent

A curing agent is not particularly limited provided that it is used commonly as a curing agent for an epoxy resin. Examples of the curing agent include a polyamine-based curing agent, an acid anhydride-based curing agent, a boron trifluoride amine complex, a phenol resin, etc.

Examples of the polyamine-based curing agent include, but are not limited to, an aliphatic amine-based curing agent such as diethylenetriamine, tetraethylenetetramine, tetraethylenepentamine, etc.; an alicyclic amine-based curing agent such as isophoronediamine, etc.; an aromatic amine-based curing agent such as diaminodiphenylmethane, phenylenediamine, etc.; dicyandiamide; etc.

Examples of the acid anhydride-based curing agent include, but are not limited to, phthalic anhydride, pyromellitic anhydride, trimellitic anhydride, hexahydrophthalic anhydride, etc. Among them, it is preferable to use an acid anhydride-based curing agent capable of imparting superior heat resistance to a flexible metal clad laminate. The above-described curing agents may be used alone or in combination of to two or more.

The content of the curing agent is not particularly limited, but may range from 0.5 to 20 parts by weight, preferably from 1 to 15 parts by weight, based on 100 parts by weight of the halogen-free epoxy resin.

Curing Accelerator

A curing accelerator is optionally used, but it is preferable to add a curing accelerator to an adhesive composition.

A curing accelerator is not particularly limited provided that it is used to facilitate the reaction of a halogen-free epoxy resin and a curing agent. Examples of the curing accelerator include, but are not limited to, imidazole compounds such as methylimidazole and ethylisocyanates thereof, 2-phenyl imidazole, 2-phenyl-4-methylimidazole, 2-phenyl-4-methyl-5-hydroxymethylimidazole, 2-phenyl-4,5-dihydroxymethylimidazole, etc.; triorganophosphines such as triphenylphosphine, tributylphosphine, tris(p-methylphenyl)phosphine, tris(p-methoxyphenyl)phosphine, tris(p-ethoxyphenyl)phosphine, triphenylphosphine.triphenylborate, tetraphenylphosphine.tetraphenylborate, etc.; quaternary phosphonium salts; tertiary amines such as triethylene ammonium.triphenylborate, etc.; tetraphenyl borates; borofluorides such as zinc borofluoride, tin borofluoride, nickel borofluoride, etc.; octylates such as tin octylate, zinc octylate, etc. These curing accelerators may be used alone or in combination of two or more.

The content of the curing accelerator is not particularly limited but may range from 0.1 to 15 parts by weight, preferably from 0.5 to 10 parts by weight, particularly preferably from 1 to 5 parts by weight, based on 100 parts by weight of the epoxy resin.

Phosphinate

Phosphinate and/or diphosphinate (hereinafter, referred to simply as “phosphinate”) is a flame retardant containing no halogen atoms.

Preferably, phosphinate may have an alkyl group of 1 to 3 carbon atoms, in particular an ethyl group. Phosphinate in which a metal constituting the salt is aluminum is particularly preferred. Phosphinate to has a higher phosphorus content, thus ensuring excellent flame retardance, in particular.

Phosphinate as used herein may have an average particle size of 20 μm or less, more preferably from 0.1 to 10 μm. If the average particle size of phosphinate is too large or small, an epoxy adhesive composition may exhibit poor dispersibility, flame retardance, heat resistance, insulating property.

For example, phosphinate may be commercially available Exolit OP930 (Clariant Ltd., aluminum diethylphosphinate, phosphorus content: 23% by mass), etc.

As used herein, the term “average particle size” refers to a volume average particle diameter measured by a laser diffraction/scattering method.

Phosphinate may be used in combination with another phosphorous retardant provided that anti-migration property is not adversely affected, but the use of only phosphinate is preferred. The combination of phosphinate with phosphoric ester is not preferable since phosphoric ester may adversely affect anti-migration property.

The content of phosphinate is not particularly limited, but may be adjusted so that a phosphorus content is a range from 2.0 to 4.5 parts by weight, more preferably from 2.5 to 4.0 parts by weight, based on 100 parts by weight of organic resin components excluding inorganic solid components (e.g., an inorganic filler) from an adhesive composition, in view of desired flame retardance.

Inorganic Filler

An inorganic filler other than the above phosphinate may be used. The inorganic filler is not particularly limited provided that it can be generally used in adhesive sheets, coverlay films and flexible copper clad laminates. The inorganic filler may be metal oxide such as aluminum oxide, magnesium hydroxide, silicon dioxide, molybdenum oxide, etc. in order to be used as a flame retardant assistant. Preferably, the inorganic filler may be aluminum hydroxide or magnesium hydroxide. These inorganic fillers may be used alone or in combination of two or to more.

The content of the inorganic filler is not particularly limited, but may range from 5 to 50 parts by weight, more preferably from 10 to 40 parts by weight, based on 100 parts by weight of organic resin components in an adhesive composition.

Organic Solvent

The above epoxy adhesive components may be used in the preparation of a flexible metal clad laminate in the absence of a solvent. Alternatively, the epoxy adhesive components may be dissolved or dispersed in an organic solvent to prepare an adhesive composition in the form of a solution or dispersion (hereinafter, referred to simply as “solution”).

Examples of the organic solvent include, but are not limited to, N,N-dimethylacetamide, methylethyl ketone, N,N-dimethylformamide, cyclohexanone, N-methyl-2-pyrrolidone, toluene, methanol, ethanol, isopropanol, acetone, etc., preferably N,N-dimethylacetamide, methylethyl ketone, N,N-dimethylformamide, cyclohexanone, N-methyl-2-pyrrolidone, and toluene, particularly preferably N,N-dimethylacetamide, methylethylketone, and toluene. These organic solvents may be used alone or in combination of two or more.

The concentration of solids (i.e., organic resin components and inorganic solid components) excluding the organic solvent from the adhesive solution is generally a range from 10 to 45 wt %, preferably from 20 to 40 wt %. If the concentration of the solids in the adhesive solution satisfies with the above range, the adhesive solution exhibits easier application to a substrate such as an electrically insulating film, thereby ensuring good workability. Also, the adhesive solution can exhibit good coating property without causing irregularities, and is environmentally and economically effective.

If necessary, the inventive epoxy adhesive composition may further include a plasticizer, an antioxidant, a flame retardant, a dispersant, a viscosity modifier, a leveling agent, or other additive(s) commonly known in the art, with proviso that the objects and effects of to the present invention are not adversely affected.

Organic resin components, optional inorganic solid components and organic solvent in the inventive epoxy adhesive composition may be mixed by means of a pot mill, a ball mill, a homogenizer, a super mill, etc.

The coating of the above-described epoxy adhesive composition on the first and/or second polyimide layer may be performed by one of various coating methods commonly known in the art, e.g., dip coating, die coating, roll coating, comma coating, casting or a combination thereof. The drying of the coated epoxy adhesive layer and the joining of the first and second polyimide layers via the adhesive layer may also be performed by appropriately adjusting temperature and pressure ranges commonly known in the art.

The present invention also provides a flexible printed circuit board including the above-described flexible metal clad laminate.

The flexible printed circuit board can exhibit various excellent properties due to polyimide, including heat resistance, insulation withstand capability, flexibility, flame retardance, chemical resistance, etc., thereby ensuring high performance and elongated lifetime of various electronic devices.

Hereinafter, the present invention will be described more specifically with reference to the following examples. The following examples are only for illustrative purposes and are not intended to limit the scope of the invention.

### Example 1

### Manufacture of Flexible Copper Clad Laminate

1-1. Formation of Polymide Layer

A solution of 9.733 g of p-phenylenediamine (p-PDA) (0.09 mol) and 12.014 g of 4,4′-oxydianiline (4,4′-ODA) (0.06 mol) in 500 ml of N-methylpyrrolidone (NMP) was added to a 1000 ml four neck round-bottom flask equipped with a thermometer, an agitator, a nitrogen inlet and a powder dispensing funnel, under nitrogen flow, and the reaction mixture was stirred so that all the components were completely dissolved. Then, the reaction solution was maintained at 50° C., 30.893 g of 3,3′,4,4′-biphenyltetracarboxylic dianhydride (BPDA) (0.105 mol) and 9.815 g of pyrromelitic dianhydride (PMDA) (0.045 mol) were gradually added thereto, and the resultant solution was stirred so that polymerization occurred to thereby give a polyamic acid varnish with a viscosity of 25,000 cps.

Thus-prepared polyamic acid varnish was coated on an electrolytic copper foil (thickness: 12 μm, ILJIN Copper Foil Co., Ltd.) using a doctor blade. At this time, a coating thickness was adjusted so that a polyimide resin layer obtained after curing had a thickness of 6 μm. Then, the resultant structure was dried at 140° C. for three minutes, then at 200° C. for five minutes, and heated to 350° C. so that imidization occurred to thereby give a polyimide-copper clad laminate.

1-2. Preparation of Epoxy Adhesive Composition

According to compositional data presented in Table 1 below, components for an epoxy adhesive composition were mixed, and a mixed solvent of methylethylketone/toluene (mass ratio: 1:1) was added thereto to thereby prepare a dispersion solution (the total content of organic solid components and inorganic solid components was 30% by mass).

TABLE 1

| Component | | Ratio |
|---|---|---|
| Phosphorus-containing epoxy resin | EJ-551 | 27 |
| Epoxy resin | AS-315 | 10 |
| | NC-3000H | 12 |
| NBR rubber | 1072 | 20 |
| Halogen-free flame retardant | SPB-100 | 10 |
| Curing agent | DICY | 1 |
| Curing accelerator | RF-30 | 0.3 |
| Aluminum hydroxide | Al2O3 | 20 |

1-3. Manufacture of Flexible Copper Clad Laminate

The polyimide surface of the copper clad laminate prepared in Example 1-1 was subjected to plasma treatment. Then, the dispersion solution prepared in Example 1-2 was coated on the polyimide surface using an applicator so that the coated layer had a thickness of 4 μm after the subsequent drying, and then dried at 130° C. for five minutes in an air circulating oven so that the coated layer was in a semi-cured state. The epoxy adhesive surfaces of thus-prepared two products were joined together, thermally pressed at 130° C. under a nip pressure of 20 N/cm using a roll laminator, and post-cured at 80° C. for two hours and then at 160° C. for four hours to thereby obtain a flexible copper clad laminate (see FIG. 2).

### Example 2

A solution of 9.733 g of p-phenylenediamine (p-PDA) (0.09 mol) and 12.014 g of 4,4′-oxydianiline (4,4′-ODA) (0.06 mol) in 500 ml of N-methylpyrrolidone (NMP) were added to a 1000 ml four neck round-bottom flask equipped with a thermometer, an agitator, a nitrogen inlet and a powder dispensing funnel, under nitrogen flow, and the reaction mixture was stirred so that all the components were completely dissolved. 14.7 g of talc was then added thereto and the resultant mixture was stirred for 30 minutes.

The reaction solution was maintained at 50° C., 30.893 g of 3,3′,4,4′-biphenyltetracarboxylic dianhydride (BPDA) (0.105 mol) and 9.815 g of pyrromelitic dianhydride (PMDA) (0.045 mol) were gradually added thereto, and the resultant solution was stirred so that polymerization occurred to thereby give a polyamic acid varnish with a viscosity of 23,000 cps. Thus-prepared polyamic acid varnish was coated on an electrolytic copper foil (thickness: 12 μm, ILJIN Copper Foil Co., Ltd.) using a doctor blade. At this time, a coating thickness was adjusted so that a polyimide resin layer obtained after curing had a thickness of 6 μm. Then, the resultant structure was dried at 140° C. for three minutes, then at 200° C. for five minutes, and heated to 350° C. so that imidization occurred to thereby give a polyimide-copper clad laminate.

An epoxy adhesive composition as prepared in Example 1-2 was coated on the copper clad laminate, followed by drying and joining, to thereby obtain a flexible copper clad laminate. The characteristics of the flexible copper clad laminate were evaluated and presented in Table 3 below.

### Examples 3˜6

Flexible copper clad laminates were manufactured in the same manner as in Example 1 except that the contents of p-PDA, ODA, BPDA, PMDA, and talc were as presented in Table 2 below. Characteristics of the flexible copper clad laminates were evaluated and presented in Table 3 below.

TABLE 2

| Example | p-PDA | ODA | BPDA | PMDA | Talc | NMP |
|---|---|---|---|---|---|---|
| 1 | 9.749 | 12.014 | 30.893 | 9.815 | — | 500 |
| 2 | 9.749 | 12.014 | 30.893 | 9.815 | 14.7 | 500 |
| 3 | 9.749 | 12.014 | 17.653 | 19.631 | — | 500 |
| 4 | 9.749 | 12.014 | 17.653 | 19.631 | 14.7 | 500 |
| 5 | 15.161 | 12.014 | 29.422 | 21.812 | — | 500 |
| 6 | 15.161 | 12.014 | 29.422 | 21.812 | 19.5 | 500 |

### Comparative Example 1

An epoxy-based adhesive composition as presented in Example 1-2 was coated on a surface of a polyimide film (Apical NPI, Kaneka, thickness: 12.5 μm) using an applicator so that a coated layer had a thickness of 4 μm after the subsequent drying, and then dried at 130° C. for three minutes in an air circulating oven so that the composition was in a semi-cured state. Then, the adhesive composition was coated on the other surface of the polyimide film using an applicator so that a coated layer had a thickness of 4 μm after the subsequent drying and then dried to at 130° C. for five minutes in an air circulating oven.

Thus-prepared polyimide film was inserted between electrolytic copper foils. The resultant structure was thermally pressed at 130° C. under a nip pressure of 20 N/cm using a roll laminator, and post-cured at 80° C. for two hours and then at 160° C. for four hours to thereby obtain a flexible copper clad laminate.

### Comparative Example 2

### 2-1. Preparation of Polyamic Acid Varnish

A solution of 49.51 g of 2,2-bis[4-(4-aminophenoxy)phenyl)propane (BAPP) (0.121 mol) in 500 ml of N-methylpyrrolidone (NMP) was added to a 1000 ml four neck round-bottom flask equipped with a thermometer, an agitator, a nitrogen inlet and a powder dispensing funnel, under nitrogen flow, and the reaction mixture was stirred so that all the components were completely dissolved. The reaction solution was maintained at 50° C., 35.49 g of 3,3′,4,4′-biphenyltetracarboxylic dianhydride (BPDA) (0.121 mol) was gradually added thereto, and the resultant solution was stirred so that polymerization occurred to thereby give a polyamic acid varnish with a viscosity of 20,000 cps.

### 2-2. Manufacture of Flexible Copper Clad Laminate

The polyimide surface of a copper clad laminate as prepared in Example 1-1 was subjected to plasma treatment. Then, the thermoplastic polyamic acid varnish prepared in Comparative Example 2-1 was coated on the polyimide surface using an applicator so that the coated layer had a thickness of 4 μm after the subsequent drying, and then dried at 140° C. for three minutes, then at 250° C. for five minutes.

The thermoplastic polyimide surfaces of thus-prepared two products were joined together, and thermally pressed under high temperature and pressure conditions (i.e., 370° C. under a nip pressure of 20 KN/cm) using a roll laminator to thereby obtain a double-sided flexible copper clad laminate.

In the preparation of the copper clad laminate of Comparative Example 2 as described above, severe adhesion conditions (e.g., high temperature, high pressure) are inevitably required, thereby making process inefficient.

### Experimental Example 1

### Evaluation of Flexible Copper Clad Laminates

The performances of the flexible copper clad laminates prepared in Examples 1-6 and Comparative Example 1 were evaluated as follows and the results are presented in Table 3 below.

1) Peel strength

The peel strength was evaluated in accordance with JIS C6471, by forming a circuit with a pattern width of 1 mm on a flexible copper clad laminate and measuring the minimum value for the force required to peel a copper foil (the circuit) at a speed of 50 mm/minute in a direction of an angle of 90 degrees with respect to a surface of the laminate at 25° C.

2) Solder heat resistance

The solder heat resistance was evaluated in accordance with JIS C6471, by preparing test specimens by cutting a flexible copper clad laminate into 25 mm squares and then floating these test specimens for 30 seconds on a 300° C. solder bath. If the test specimens exhibited no blistering, peeling or discoloration, the solder heat resistance was evaluated as “good” and recorded as “◯”, whereas if the test specimens exhibited at least one of blistering, peeling and discoloration, the solder heat resistance was evaluated as “poor” and recorded as “X”.

3) Flame Retardance

A sample was prepared by completely removing a copper foil from a flexible copper clad laminate through an etching treatment.

The flame retardance of the sample was evaluated in accordance with the flame retardance standard UL94V-0. If the sample satisfied with the UL94V-0 standard, it was evaluated as “good” and recorded as “◯”, whereas if the sample did not satisfy with the UL94V-0 standard, it was evaluated as “poor” and recorded as “X”.

4) Flexibility

Flexibility was evaluated in accordance with JIS C6471, by forming a circuit with a pattern width of 1 mm on a flexible copper clad laminate, adhering a coverlay thereto and measuring the number of folds under conditions of a curvature radius of a bending portion of 0.38 mm and a load of 500 g.

TABLE 3

| | Peel strength | Solder heat | Flame | |
|---|---|---|---|---|
| | of copper foil | resistance | retardancy | |
| Sample | (Kgf/cm) | (@300° C.) | (UL94V-0) | Flexibility |
| Example 1 | 1.2 | ◯ | ◯ | 5,600 |
| Example 2 | 1.2 | ◯ | ◯ | 5,100 |
| Example 3 | 1.1 | ◯ | ◯ | 4,700 |
| Example 4 | 1.1 | ◯ | ◯ | 4,400 |
| Example 5 | 1.2 | ◯ | ◯ | 4,800 |
| Example 6 | 1.2 | ◯ | ◯ | 4,000 |
| Comparative | 1.3 | ◯ | ◯ | 2,500 |
| Example 1 | | | | |

As shown in Table 3, the flexible copper clad laminate of Comparative Example 1 exhibited very poor flexibility, whereas the inventive flexible copper clad laminates were excellent in terms of all essential properties required for flexible copper clad laminates, e.g., heat resistance, flame retardance, flexibility, peel strength of copper foil, etc.

Unlike the manufacture of the flexible copper clad laminate of Comparative Example 2 requiring severe adhesion conditions (e.g., high temperature, high pressure), the inventive manufacturing method is to relatively simple, and thus, can be effectively applied in the various fields of flexible printed circuit boards.

1. A flexible metal clad laminate comprising:
(a) a first conductive metal foil in which a first polyimide layer is formed on a surface thereof; and
(b) a second conductive metal foil in which a second polyimide layer is formed on a surface thereof,
wherein the first polyimide layer and the second polyimide layer are joined together by an epoxy adhesive.

2. The flexible metal clad laminate of claim 1, comprising a sequentially stacked array of (a) the first conductive metal foil, (b) the first polyimide layer, (c) an epoxy adhesive layer, (d) the second polyimide layer, and (e) the second conductive metal foil.

3. The flexible metal clad laminate of claim 1, wherein each of the first and second conductive metal foils has a thickness ranging from 5 to 40 μm, each of the first and second polyimide layers has a thickness ranging from 2 to 60 μm, and the epoxy adhesive is formed to a thickness ranging from 2 to 60 μm.

4. The flexible metal clad laminate of claim 1, wherein each of the first and second conductive metal foils is made of copper, tin, gold, silver or a combination thereof.

5. The flexible metal clad laminate of claim 1, wherein an inorganic filler reducing coefficient of thermal expansion (CTE) of the first and second polyimide layers is uniformly distributed or localized in each of the first and second polyimide layers.

6. A flexible printed circuit board comprising the flexible metal clad laminate of claim 1.

7. A method of manufacturing the flexible metal clad laminate of claim 1, the method comprising:
(a) forming a first polyimide layer on a first conductive metal foil, followed by curing;
(b) forming a second polyimide layer on a second conductive metal foil, followed by curing; and
(c) coating an epoxy adhesive on at least one of the first polyimide layer and the second polyimide layer, followed by drying so that the epoxy adhesive is in a semi-cured state, and joining the first polyimide layer and the second polyimide layer.
